(19) United States
(12) Patent Application Publication
(10) Pub. No.: US 2015/0057393 A1
(43) Pub. Date: Feb. 26, 2015

(54) INSULATING RESIN COMPOSITION FOR PRINTED CIRCUIT BOARD AND PRODUCTS MANUFACTURED BY USING THE SAME

(71) Applicant: SAMSUNG ELECTRO-MECHANICS CO., LTD., Suwon (KR)

(72) Inventors: Jin Seok Moon, Suwon (KR); Hyun Jun Lee, Suwon (KR); Seong Hyun Yoo, Suwon (KR); Jin Young Kim, Suwon (KR); Geum Hee Yun, Suwon (KR)

(73) Assignee: SAMSUNG ELECTRO-MECHANICS CO., LTD., Suwon (KR)

(21) Appl. No.: 14/095,864

(22) Filed: Dec. 3, 2013

(30) Foreign Application Priority Data
Aug. 26, 2013 (KR) 10-2013-0101246

(51) Int. Cl. H05K 1/03; H05K 3/00

(52) U.S. Cl. CPC H05K 1/0373; H05K 3/0011; H05K 3/0091; H05K 1/0353
USPC 523/435; 427/96.1

(57) ABSTRACT

Disclosed herein are an insulating resin composition for a printed circuit board and products manufactured by using the same, and more particularly, an insulating resin composition for a printed circuit board including a 4-functional naphthalene-based epoxy resin and having improved coefficient of thermal expansion and glass transition temperature properties, and a prepreg and a printed circuit board as products manufactured by using the same.

### CROSS REFERENCE TO RELATED APPLICATION

This application claims the benefit of Korean Patent Application No. 10-2013-0101246, filed on Aug. 26, 2013, entitled “Insulating Resin Composition for Printed Circuit Board and Products Having the Same”, which is hereby incorporated by reference in its entirety into this application.

### BACKGROUND OF THE INVENTION

1. Technical Field

The present invention relates to an insulating resin composition for a printed circuit board and products manufactured by using the same.

2. Description of the Related Art

In accordance with the development of electronic devices, a printed circuit board has progressed to have light weight, thin thickness, and small size. In order to satisfy the demand in lightness and slimness as described above, wirings of the printed circuit board become more complicated and are densely formed. Electrical, thermal, and mechanical properties required for the board as described above function as a more important factor. The printed circuit board is configured of a copper mainly serving as a circuit wiring and a polymer serving as an interlayer insulation. As compared to the copper, various properties such as coefficient of thermal expansion, glass transition temperature, and thickness uniformity, are demanded in a polymer configuring an insulating layer, in particular, the insulating layer should be designed so as to have a thin thickness.

As the circuit board becomes thin, the board itself has decreased rigidity, causing defects due to a bending phenomenon at the time of mounting components thereon at a high temperature. Therefore, thermal expansion property and heat-resistant property of a heat curable polymer resin function as an important factor, that is, at the time of heat curing, network between polymer chains configuring a polymer structure and a board composition and curing density are closely affected.

In the prior art, a board forming composition for forming a board including a liquid crystal oligomer and an epoxy-based resin is disclosed, wherein the liquid crystal oligomer is an oligomer having liquid crystallinity and including hydroxyl groups introduced at both ends, and the epoxy-based resin has four functional groups introduced therein, that is, N,N,N′,N′-Tetraglycidyl-4,4′-methylene bisbenzenamine. The liquid crystal oligomer and the epoxy-based resin are mixed in N,N′-dimethylacetamide (DMAc) together with dicyandiamide in a predetermined mixed ratio to prepare the composition. In order to cure the liquid crystal oligomer having the hydroxyl group introduced therein in the composition, the epoxy-based resin, N,N,N′,N′-Tetraglycidyl-4,4′-methylenebisbenzenamine is added for heat curing, which is not appropriate in view of decrease in coefficient of thermal expansion (CTE) and increase in glass transition temperature (Tg) that are important in materials of the printed board, due to flexibility in molecular chains between the hydroxyl group and epoxy-based resin produced by reaction with multi-functional epoxy resin.

Meanwhile, Patent Document 1 discloses a resin composition for a printed circuit board, but has a limitation in sufficiently forming interaction network in compositions, such that coefficient of thermal expansion and glass transition temperature properties of the printed circuit board are not improved.

### PRIOR ART DOCUMENT

(Patent Document 1) Korean Patent Laid-Open Publication No. KR 2011-0108782

### SUMMARY OF THE INVENTION

In the present invention, it is confirmed that an insulating resin composition for a printed circuit board, the insulating resin composition including a liquid crystal oligomer (LCO); a 4-functional naphthalene-based epoxy resin; and a bismaleimide resin, and products manufactured by using the same have improved coefficient of thermal expansion and glass transition temperature properties, thereby completing the present invention.

Therefore, the present invention has been made in an effort to provide the insulating resin composition for the printed circuit board having the improved coefficient of thermal expansion and glass transition temperature properties.

In addition, the present invention has been made in an effort to provide a prepreg prepared by impregnating an inorganic fiber or an organic fiber into a varnish containing the insulating resin composition.

Further, the present invention has been made in an effort to provide a printed circuit board manufactured by using the prepreg.

According to a preferred embodiment of the present invention, there is provided an insulating resin composition for a printed circuit board including: a liquid crystal oligomer (LCO); a 4-functional naphthalene-based epoxy resin; and a bismaleimide resin.

The insulating resin composition may include the liquid crystal oligomer (LCO) in an amount of 30 to 55 wt %, the 4-functional naphthalene-based epoxy resin in an amount of 30 to 55 wt %, and the bismaleimide resin in an amount of 10 to 40 wt %.

The liquid crystal oligomer may be represented by the following Chemical Formula 1:

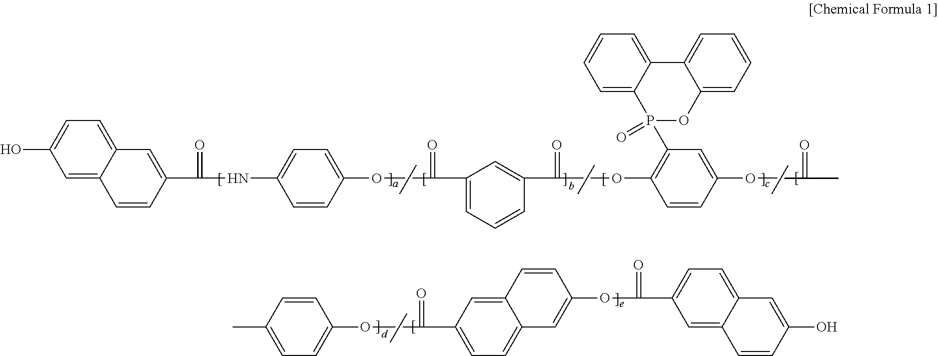

in Chemical Formula 1, a is an integer of 13 to 26, b is an integer of 13 to 26, c is an integer of 9 to 21, d is an integer of 10 to 30, and e is an integer of 10 to 30.

The 4-functional naphthalene-based epoxy resin may be bis(2,7-bis(2,3-epoxypropoxy))dinaphthalene methane represented by the following Chemical Formula 2:

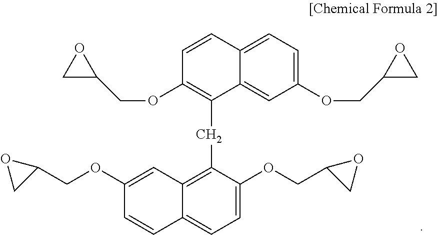 [SMILES: c1cc2ccc(OCC3CO3)c(Cc3c(OCC4CO4)ccc4ccc(OCC5CO5)cc34)c2cc1OCC1CO1]

The bismaleimide resin may be an oligomer of phenyl methane maleimide represented by the following Chemical Formula 3:

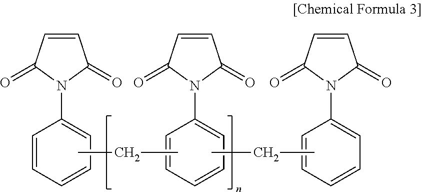

in Chemical Formula 3, n is an integer of 1 or 2.

The insulating resin composition may further include an inorganic filler, a curing agent, a curing accelerator, and an initiator.

The inorganic filler may be included in an amount of 100 to 400 parts by weight based on 100 parts by weight of the insulating resin composition, and may be at least one selected from silica (SiO₂), alumina (Al₂O₃), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

The curing agent may be included in an amount of 0.1 to 10 parts by weight based on 100 parts by weight of the insulating resin composition, and may be at least one selected from an amine-based curing agent, an acid anhydride-based curing agent, a polyamine curing agent, a polysulfide curing agent, a phenol novolak type curing agent, a bisphenol A type curing agent, and a dicyandiamide curing agent.

The curing accelerator may be included in an amount of 0.10 to 1 part by weight based on 100 parts by weight of the insulating resin composition, and may be at least one selected from a metal-based curing accelerator, an imidazole-based curing accelerator, and an amine-based curing accelerator.

The initiator may be at least one selected from azobisisobutyronitrile (AIBN), dicumyl peroxide (DCP) and di-tertiarybutyl peroxide (DTBP).

According to another preferred embodiment of the present invention, there is provided a prepreg prepared by impregnating an inorganic fiber or an organic fiber into a varnish containing the insulating resin composition as described above.

The inorganic fiber or the organic fiber may be at least one selected from a glass fiber, a carbon fiber, a polyparaphenylene benzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber.

According to another preferred embodiment of the present invention, there is provided a printed circuit board manufactured by using the prepreg as described above.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a general printed circuit board to which an insulating resin composition according to a preferred embodiment of the present invention may be applied.

### DESCRIPTION OF THE PREFERRED EMBODIMENTS

Before the present invention is described in more detail, it must be noted that the terms and words used in the present specification and claims should not be interpreted as being limited to typical meanings or dictionary definitions, but should be interpreted as having meanings and concepts relevant to the technical scope of the present invention based on the rule according to which an inventor can appropriately define a concept implied by a term to best describe the method he or she knows for carrying out the invention. Further, the embodiments of the present invention are merely illustrative, and are not to be construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related to the present invention may make the gist of the present invention unclear, a detailed description thereof will be omitted.

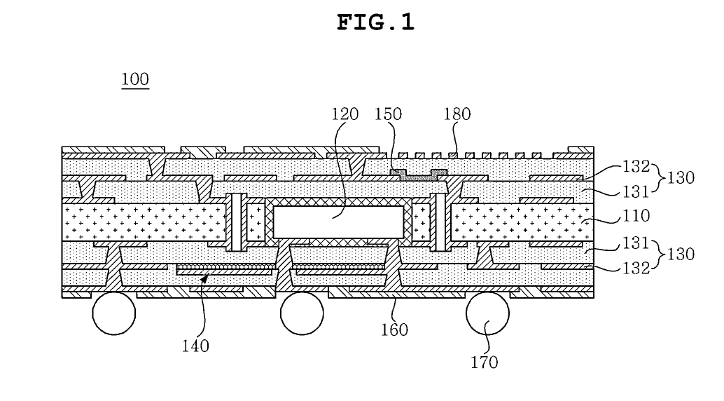

FIG. 1 is a cross-sectional view of a general printed circuit board to which an insulating resin composition according to a preferred embodiment of the present invention may be applied, and referring to FIG. 1, a printed circuit board 100 may be an embedded board with a built-in electronic component. More specifically, the printed circuit board 100 may include an insulator 110 having cavities, electronic components 120 disposed in the cavities, and a build-up layer 130 disposed on at least one of upper and lower surfaces of the insulator 110 including the electronic component 120. The buildup layer 130 may include an circuit layer 132 disposed on an insulating layer 131 disposed on at least one surface of the upper and lower surfaces of the insulator 110 and forming an interlayer connection. Here, an example of the electronic component 120 may include an active device such as a semiconductor device. In addition, in the printed circuit board 100, only one electronic component 120 is not embedded but at least one additional electronic component such as a capacitor 140 and a resistor device 150 may be embedded. Therefore, the preferred embodiment of the present invention is not limited in view of types or the number of electronic components. Further, in order to protect the printed circuit board, a solder resist 160 layer may be provided in the outermost portion. The printed circuit board may be provided with external connection units 170 according to electronic products to be mounted thereon, and sometimes provided with a pad 180 layer. Herein, the insulator 110 and the insulating layer 131 may serve to provide inter-circuit layer insulation and inter-electronic component insulation and also serve as a structural member for maintaining rigidity of the package. In this case, when a wiring density of the printed circuit board 100 is increased, the insulator 110 and the insulating layer 131 are required to have low dielectric constant in order to reduce both inter-circuit layer noise and parasitic capacitance, and are required to have low dielectric loss property in order to increase the insulating property. As described above, at least any one of the insulator 110 and the insulating layer 131 are required to have rigidity and decreased dielectric constant and decreased dielectric loss.

In order to secure the rigidity by decreasing the coefficient of thermal expansion and increasing the glass transition temperature in α₂ (270° C. to 300° C.) zone of the insulating layer 131 in the preferred embodiment of the present invention, the insulating layer 131 and the insulator 110 may be formed as the insulating resin composition for the printed circuit board, including a liquid crystal oligomer (LCO); a 4-functional naphthalene-based epoxy resin; and a bismaleimide resin.

Liquid Crystal Oligomer

The insulating resin composition according to the preferred embodiment of the present invention may include a liquid crystal oligomer in which hydroxyl groups are introduced at both ends, represented by the following Chemical Formula 1:

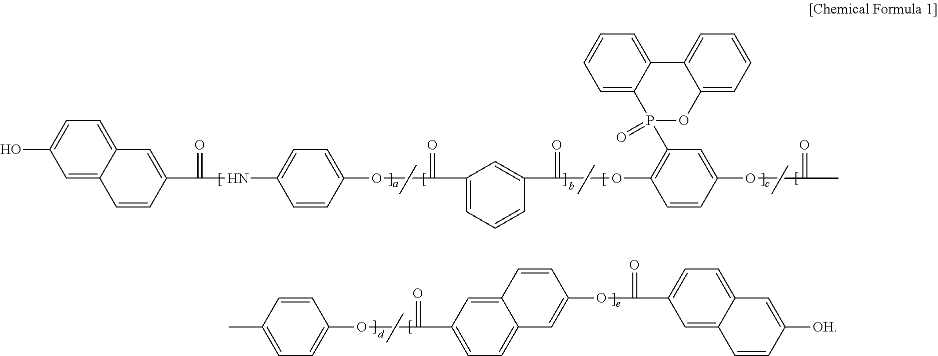

In Chemical Formula 1, a is an integer of 13 to 26; b is an integer of 13 to 26; c is an integer of 9 to 21; d is an integer of 10 to 30; and e is an integer of 10 to 30.

The liquid crystal oligomer according to the preferred embodiment of the present invention is not specifically limited in view of a used amount, but is appropriate for being used in an amount of 30 to 55 wt %. In the case in which the used amount is less than 30 wt %, decrease in coefficient of thermal expansion and increase in glass transition temperature are not significant, and in the case in which the used amount is more than 55 wt %, mechanical physical properties are deteriorated.

The liquid crystal oligomer has a number average molecular weight of, preferably, 2500 to 6500 g/mol, and more preferably, 3000 to 5,500 g/mol, and most preferably, 3500 to 5000 g/mol. In the case in which the number average molecular weight of the liquid crystal oligomer is less than 2500 g/mol, the mechanical physical property may be deteriorated and in the case in which the number average molecular weight of the liquid crystal oligomer is more than 6500 g/mol, solubility may be deteriorated.

4-Functional Naphthalene-based Epoxy Resin

The insulating resin composition according to the preferred embodiment of the present invention may include 4-functional naphthalene-based epoxy resin. The epoxy resin may be bis(2,7-bis(2,3-epoxypropoxy))dinaphthalene methane represented by the following Chemical Formula 2:

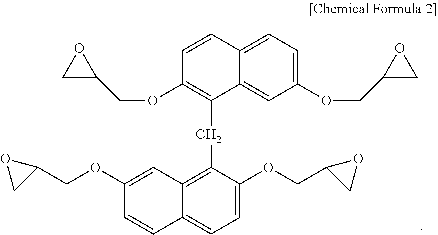 [SMILES: c1cc2ccc(OCC3CO3)c(Cc3c(OCC4CO4)ccc4ccc(OCC5CO5)cc34)c2cc1OCC1CO1]

The epoxy resin represented by Chemical Formula 2 above improves heat-resistant property in the insulating resin composition, and the epoxide functional groups introduced at ends are easily packed at the time of curing the composition and form a stacking structure in which planar chromophores such as an aromatic ring, and the like, are stacked with an overlap by dispersion or hydrophobic interaction, which have less thermal deformation. Further, the epoxy resin represented by Chemical Formula 2 above includes a naphthalene structure to be rigid, thereby having thermal stability. The bis(2,7-bis(2,3-epoxypropoxy))dinaphthalene methane which is the epoxy resin may constitute a network interconnected with the liquid crystal oligomer and the bismaleimide resin in the resin composition, which achieves high heat-resistant property.

The bis(2,7-bis(2,3-epoxypropoxy))dinaphthalene methane is not specifically limited in view of a used amount, but is appropriate for being used in an amount of 30 to 55 wt %. In the case in which the used amount is less than 30 wt %, handling property as the resin composition may be deteriorated, and in the case in which the used amount is more than 55 wt %, additional amounts of other components are relatively decreased, such that the dielectricloss tangent, the dielectric constant, and the coefficient of thermal expansion are hardly improved.

Bismaleimide Resin

The insulating resin composition according to the preferred embodiment of the present invention may include the bismaleimide resin for improving the heat-resistant property in the resin composition. The bismaleimide resin is an oligomer of phenyl methane maleimide represented by the following Chemical Formula 3:

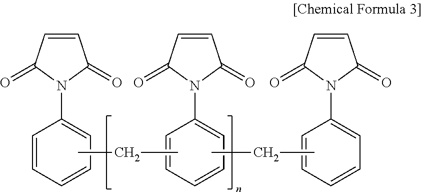

in Chemical Formula 3, n is an integer of 1 or 2.

The oligomer of phenyl methane maleimide of the present invention is not specifically limited in view of a used amount, but is appropriate for being used in an amount of 10 to 40 wt %. In the case in which the used amount is less than 10 wt %, the glass transition temperature is hardly improved, and in the case in which the used amount is more than 40 wt %, brittle is increased, such that it may be difficult to be manufactured as a product.

The oligomer of phenyl methane maleimide may constitute the network interconnected with the liquid crystal oligomer and the 4-functional naphthalene-based epoxy resin in the insulating resin composition, which achieve a synergy effect to further improve thermal property.

The insulating resin composition according to the preferred embodiment of the present invention may further include an inorganic filler, a curing agent, a curing accelerator, and an initiator.

The inorganic filler may be included in the insulating resin composition in order to decrease the coefficient of thermal expansion, wherein a ratio in which the inorganic filler is contained in the resin composition may be varied depending on properties required in consideration of the use of the resin composition, and the like, and for example, the inorganic filler may be included in an amount of 100 to 400 parts by weight based on 100 parts by weight of the insulating resin composition. In the case in which the contained amount of the inorganic filler is less than 100 parts by weight, the dielectricloss tangent is decreased and the coefficient of thermal expansion is increased, and in the case in which the contained amount of the inorganic filler is more than 400 parts by weight, adhesion strength is deteriorated.

As the inorganic filler, silica (SiO₂), alumina (Al₂O₃), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃) may be used alone or in combination of two or more kinds thereof. In particular, it is appropriate to use a silica (SiO₂) having lower dielectric loss tangent.

In the insulating resin composition according to the preferred embodiment of the present invention, the curing agent may be selectively used, and in general, any curing agent is usable as long as the agent includes reaction groups capable of reacting with the epoxide ring included in the epoxy resin, but the present invention is not particularly limited thereto.

The used amount of the curing agent may be appropriately selected in consideration of a curing rate without deteriorating unique physical properties in the range of 0.1 to 10 parts by weight based on 100 parts by weight of the insulating resin composition.

More specifically, examples of the curing agents may include an amine-based curing agent, an acid anhydride-based curing agent, a polyamine curing agent, a polysulfide curing agent, a phenol novolak type curing agent, a bisphenol A type curing agent and a dicyandiamide curing agent, and one kind or a combination of two or more kinds of curing agent may be used.

In addition, the insulating resin composition according to the preferred embodiment of the present invention may be effectively cured by selectively containing the curing accelerator. The curing accelerator used in the present invention is not specifically limited in view of a used amount, but may be included in an amount of 0.01 to 1 part by weight based on 100 parts by weight of the insulating resin composition. In addition, examples of the curing accelerator used in the present invention may include a metal-based curing accelerator, an imidazole-based curing accelerator, and an amine-based curing accelerator, and one kind or a combination of two or more kinds thereof may be used.

Examples of the metal-based curing accelerator may include an organic metal complex or an organic metal salt of a metal such as cobalt, copper, zinc, iron, nickel, manganese, tin, or the like, but the present invention is not limited thereto. Specific examples of the organic metal complex may include organic cobalt complex such as cobalt (II) acetylacetonate, cobalt (II) acetylacetonate, or the like, organic copper complex such as copper (II) acetylacetonate, organic zinc complex such as zinc (II) acetylacetonate, organic iron complex such as iron (III) acetylacetonate, organic nickel complex such as Ni (II) acetylacetonate, organic manganese complex such as manganese (II) acetylacetonate, and the like. Examples of the organic metal salts may include zinc octyl acid, tin octyl acid, zinc naphthenic acid, cobalt naphthenic acid, tin stearic acid, zinc stearic acid, and the like. As the metal-based curing accelerator, cobalt (II) acetylacetonate, cobalt (II) acetylacetonate, zinc (II) acetylacetonate, zinc naphthenic acid, iron (III) acetylacetonate is appropriate, and in particular, cobalt (II) acetylacetonate and zinc naphthenic acid is more preferred, in view of curability and solvent solubility. One kind or a combination of two or more kinds of the metal-based curing accelerator may be used.

Examples of the imidazone-based curing accelerator may include imidazole compounds such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazoliumtrimellitate, 1-cyanoethyl-2-phenylimidazoliumtrimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazineisocyanic acid adduct, 2-phenyl-imidazoleisocyanic acid adduct, 2-phenyl-4,5-dihydroxymethylimidazole, 2-phenyl-4-methyl-5-hydroxymethylimidazole, 2,3-dihydroxy-1H-pyroro[1,2-a]benzimidazole, 1-dodecyl-2-methyl-3-benzyl-imidazoliumchloride, 2-methylimidazoline, and 2-phenyl-imidazoline, and an adduct of the imidazole compounds and the epoxy resin, but the present invention is not limited thereto. One kind or a combination of two or more kinds of the imidazole-based curing accelerator may be used.

Examples of the amine-based curing accelerator may include trialkylamine such as triethylamine or tributylamine, and an amine compound such as 4-dimethylaminopyridine, benzyldimethylamine, 2,4,6-tris(dimethylamino-methyl)phenol, or 1,8-diazabicyclo(5,4,0)-undecene, but the present invention is not limited thereto. One kind or a combination of two or more kinds of the amine-based curing accelerator may be used.

In the insulating resin composition according to the preferred embodiment of the present invention, the initiator of the bismaleimide resin may be at least one selected from azobisisobutyronitrile (AIBN), dicumyl peroxide (DCP) and di-tertiarybutyl peroxide (DTBP) and may be selectively contained to generate an effective reaction.

In the insulating resin composition according to the preferred embodiment of the present invention, the bismaleimide resin, the liquid crystal oligomer, and the curing agent may have a network structure interconnected by a Michael reaction. In addition, the oligomer liquid crystal, the 4-functional naphthalene-based epoxy resin, and the curing agent may have the network structure interconnected by a nucleophilic addition. Therefore, the network in which the bismaleimide resin, the liquid crystal oligomer, the 4-functional naphthalene-based epoxy resin, and the curing agent are interconnected is constituted therein, which shows high heat-resistant property in the insulating resin composition.

Homo polymerization of the bismaleimide resin is a curing reaction by a radical polymerization, and may be represented by the following Reaction Formula 1:

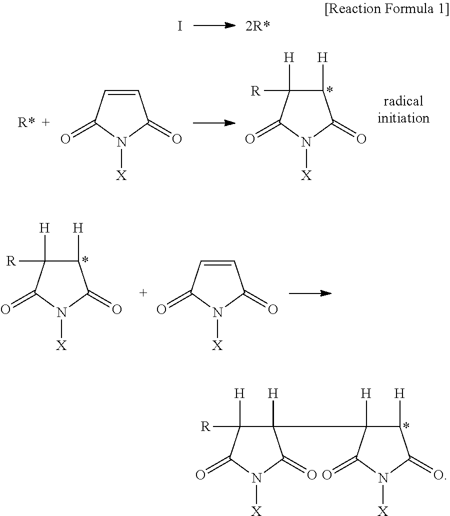

In Reaction Formula 1, R is azobisisobutyronitrile (AIBN) which is a radical initiator, and X is an aromatic phenyl group.

The Michael reaction is a reaction of a double bond of a maleimide resin, a hydroxyl group of the liquid crystal oligomer, and an amine group of the dicyandiamide (DICY) curing agent and may be represented by the following Reaction Formulas 2 and 3:

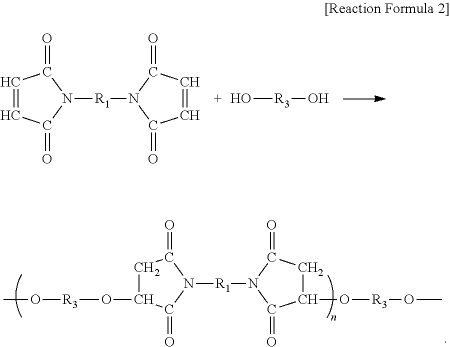

In Reaction Formula 2, R₁ is an aromatic phenyl group, R₃ is the liquid crystal oligomer represented by Chemical Formula 2 above except for hydroxyl groups (—OH) positioned at both ends:

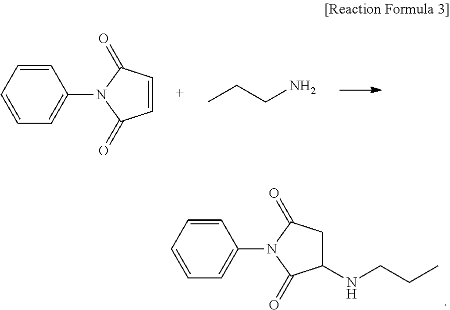

The nucleophilic addition is a reaction of an epoxide group of the 4-functional naphthalene-based epoxy resin, a hydroxyl group of the liquid crystal oligomer, and an amine group of the dicyandiamide (DICY) curing agent and may be represented by the following Reaction Formulas 4 and 5:

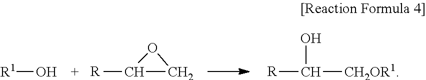

In Reaction Formula 4, R is bis(2,7-bis(2,3-epoxypropoxy))dinaphthalene methane which is the 4-functional naphthalene-based epoxy resin represented by Chemical Formula 2 above, except for one end-positioned epoxide group, and R¹ is the liquid crystal oligomer represented by Chemical Formula 1, except for the end hydroxyl group (—OH).

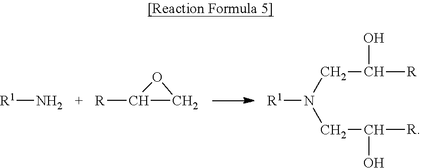

In Reaction Formula 5, R is bis(2,7-bis(2,3-epoxypropoxy))dinaphthalene methane which is the 4-functional naphthalene-based epoxy resin represented by Chemical Formula 2 above, except for one end-positioned epoxide group, and R¹ is dicyandiamide (DICY) except for the amine group (—NH₂).

The insulating resin composition according to the preferred embodiment of the present invention may be fabricated as a dry film in a semi solid state by using any general methods known in the art. For example, the film is fabricated by using a roll coater, a curtain coater, or a comma coater and dried, and then applied on a substrate to be used as the insulating layer (or the insulating film) or the prepreg at the time of manufacturing a multilayer printed circuit board by a build-up scheme. The insulating film or the prepreg may improve the coefficient of thermal expansion and the glass transition temperature properties.

As described above, the insulating resin composition according to the preferred embodiment of the present invention is impregnated into a substrate such as the inorganic fiber or the organic fiber and cured to prepare the prepreg, and a copper clad is stacked thereon to obtain a copper clad laminate (CCL). In addition, the insulating film prepared by the insulating resin composition according to the preferred embodiment of the present invention is laminated on the CCL used as an inner layer at the time of manufacturing the multilayer printed circuit board to be used in manufacturing the multilayer printed circuit board. For example, after the insulating film prepared by the insulating resin composition is laminated on an inner circuit board having processed patterns and cured at a temperature of 80 to 110° C. for 20 to 30 minutes, a desmear process is performed, and a circuit layer is formed through an electroplating process, thereby manufacturing the multilayer printed circuit board.

The inorganic fiber or organic fiber may be at least one selected from a glass fiber, a carbon fiber, a polyparaphenylene benzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber.

Hereinafter, the present invention will be described in more detail with reference to the following examples and comparative examples; however, it is not limited thereto.

### Preparation of Liquid Crystal Oligomer

### Preparation Example

4-aminophennol 218.26 g (2.0 mol), isophthalic acid 415.33 g (2.5 mol), 4-hydroxybenzoic acid 276.24 g (2.0 mol), 6-hydroxy-2-naphthoic acid 282.27 g (1.5 mol), DOPO-HQ 648.54 g (2.0 mol) and acetic acid anhydride 1531.35 g (15.0 mol) were added into a 20 L glass reactor. After the inside of the glass reactor was sufficiently substituted with a nitrogen gas, a temperature in the reactor was increased to about 230° C. under the nitrogen gas flow, followed by reflux for about 4 hours while maintaining the temperature in the reactor at 230° C. Then, after end capping 6-hydroxy-2-naphtoic acid 188.18 g (1.0 mol) was further added thereto, an acetic acid which is a reaction by-product and a non-reacted acetic acid anhydride were removed, thereby preparing a liquid crystal oligomer.

### Example 1

An oligomer of phenyl methane maleimide 4 g and the liquid crystal oligomer 20 g prepared by Preparation Example above were mixed into an N,N′-dimethylacetamide (DMAc) solvent 28.12 g, followed by stirring for about 1 hour. Bis(2,7-bis(2,3-epoxypropoxy))dinaphthalene methane 16 g which is the 4-functional naphthalene-based epoxy resin was added thereto, followed by stirring for about 2 hours. Then, dicyandiamide (DICY) 0.16 g and azobisisobutyronitrile (AIBN) 0.1 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. When the curing was completed, the film was cut into a size of 4.3 mm/30 mm to prepare a measuring sample.

### Example 2

An oligomer of phenyl methane maleimide 7.5 g and the liquid crystal oligomer 15 g prepared by Preparation Example above were mixed into an N,N′-dimethylacetamide (DMAc) solvent 30.23 g, followed by stirring for about 1 hour. Bis(2,7-bis(2,3-epoxypropoxy))dinaphthalene methane 15 g which is the 4-functional naphthalene-based epoxy resin was added thereto, followed by stirring for about 2 hours. Then, dicyandiamide (DICY) 0.15 g and azobisisobutyronitrile (AIBN) 0.1875 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to prepare a measuring sample.

### Example 3

An oligomer of phenyl methane maleimide 12 g and the liquid crystal oligomer 12 g prepared by Preparation Example above were mixed into an N,N′-dimethylacetamide (DMAc) solvent 36.36 g, followed by stirring for about 1 hour. Bis(2,7-bis(2,3-epoxypropoxy))dinaphthalene methane 16 g which is the 4-functional naphthalene-based epoxy resin was added thereto, followed by stirring for about 2 hours. Then, dicyandiamide (DICY) 0.16 g and azobisisobutyronitrile (AIBN) 0.3 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to prepare a measuring sample.

### Example 4

An oligomer of phenyl methane maleimide 4 g, and the liquid crystal oligomer 20 g prepared by Preparation Example above, and a silica (SiO₂) slurry 60 g were mixed into an N,N′-dimethylacetamide (DMAc) solvent 43.12 g, followed by stirring for about 1 hour. Bis(2,7-bis(2,3-epoxypropoxy))dinaphthalene methane 16 g which is the 4-functional naphthalene-based epoxy resin was added thereto, followed by stirring for about 2 hours. Then, dicyandiamide (DICY) 0.16 g and azobisisobutyronitrile (AIBN) 0.1 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to prepare a measuring sample.

### Example 5

An oligomer of phenyl methane maleimide 7.5 g, the liquid crystal oligomer 15 g prepared by Preparation Example above, and a silica ((SiO₂) slurry 56.24 g were mixed into an N,N′-dimethylacetamide (DMAc) solvent 44.29 g, followed by stirring for about 1 hour. Bis(2,7-bis(2,3-epoxypropoxy))dinaphthalene methane 15 g which is the 4-functional naphthalene-based epoxy resin was added thereto, followed by stirring for about 2 hours. Then, dicyandiamide (DICY) 0.15 g and azobisisobutyronitrile (AIBN) 0.1875 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to prepare a measuring sample.

### Production of Prepreg

### Example 6

An oligomer of phenyl methane maleimide 4 g, and the liquid crystal oligomer 20 g prepared by Preparation Example above, and a silica (SiO₂) slurry 60 g were mixed into an N,N′-dimethylacetamide (DMAc) solvent 43.12 g, followed by stirring for about 1 hour. Bis(2,7-bis(2,3-epoxypropoxy))dinaphthalene methane 16 g which is the 4-functional naphthalene-based epoxy resin was added thereto, followed by stirring for about 2 hours. Then, dicyandiamide (DICY) 0.16 g and azobisisobutyronitrile (AIBN) 0.1 g were added thereto, followed by stirring for about 1 hour, thereby preparing a completely dissolved resin composition. When the stirring was completed, an organic fiber or an inorganic fiber was impregnated into a varnish containing the resin composition and the reactant was put into the oven and dried at about 120° C. for 15 minutes. When the drying was completed, the temperature was increased up to 220° C., and the reactant was completely cured by maintaining a temperature of about 220° C., and pressure of 30 kgf/cm² for about 90 minutes to prepare a prepreg.

### Manufacture of Printed Circuit Board

### Example 7

Copper clad layers were stacked on both surfaces of the prepreg prepared by Example 6 above and a circuit pattern was formed thereon. Then, after a drying process was performed under conditions of about 120° C. for 30 minutes, the insulating film prepared by Example 3 above was stacked on the board having the circuit pattern formed thereon, and was vacuum laminated by using a Morton CVA 725 vacuum laminator under conditions of about 90° C. and 2 MPa for about 20 seconds, thereby manufacturing a printed circuit board.

### Comparative Example 1

The liquid crystal oligomer 20 g prepared by Preparation Example above was mixed into an N,N′-dimethylacetamide (DMAc) solvent 24 g, followed by stirring for about 1 hour. A 2-functional epoxy resin, Araldite MY-721 (Huntsman Corporation) 16 g was added thereto, followed by stirring for about 2 hours. Then, dicyandiamide (DICY) 0.16 g and azobisisobutyronitrile (AIBN) 0.1 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to prepare a measuring sample.

### Comparative Example 2

The liquid crystal oligomer 15 g prepared by Preparation Example 1 above was mixed into an N,N′-dimethylacetamide (DMAc) solvent 19 g, followed by stirring for about 1 hour. A 3-functional epoxy resin, Araldite MY-721 (Huntsman Corporation) 15 g was added thereto, followed by stirring for about 2 hours. Then, dicyandiamide (DICY) 0.15 g and azobisisobutyronitrile (AIBN) 0.1875 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to prepare a measuring sample.

Coefficients of thermal expansion of the insulating films prepared by Examples 1 to 3 and Comparative Examples 1 and 2 were measured in a tensile mode by using a thermomechanical analyzer (TMA) of TA Company, including primarily scanning for 10° C. per minute up to about 300° C., and after cooling, secondarily scanning for 10° C. per minute up to about 310° C., and then measuring the coefficients of thermal expansion in α₁ (50° C. to 100° C.) and α₂ (270° C. to 300° C.) zone from resultant values obtained by the second scanning. In addition, glass transition temperatures (Tg) were measured by using a differential scanning calorimeter (DSC) of TA Company, including putting each prepared insulating film 5 mg into the DSC, primarily measuring for 10° C. per minute up to about 300° C., and after cooling, secondarily measuring for 10° C. per minute up to about 300° C., and measuring the glass transition temperatures (Tg) from resultant values obtained by the second measuring.

TABLE 1

| | Coefficient | Coefficient | |
|---|---|---|---|
| | of Thermal | of Thermal | |
| | Expansion (CTE) | Expansion (CTE) | Glass Transition |
| | (α₁) | (α₂) | Temperature (Tg) |
| Classification | (ppm/° C.) | (ppm/° C.) | (° C.) |
| Example 1 | 47.8 | 126.6 | 285 |
| Example 2 | 47.2 | 102.1 | 307 |
| Example 3 | 49.0 | 96.6 | 325 |
| Comparative | 45.3 | 163.5 | 247 |
| Example 1 | | | |
| Comparative | 46.2 | 165.7 | 242 |
| Example 2 | | | |

It may be appreciated from Table 1 above that at the time of measuring the coefficients of thermal expansion in α₁ (50° C. to 100° C.) zone, the coefficients of thermal expansion of Examples 1 to 3 were slightly smaller than those of Comparative Examples 1 and 2; however, in α₂ (27° C.˜300° C.) zone which has a temperature section higher than the glass transition temperature, the coefficients of thermal expansion of Examples 1 to 3 were remarkably excellent than those of Comparative Examples 1 and 2. Accordingly, it may be appreciated that in Samples of Examples 1 to 3 prepared by including the insulating resin composition according to the preferred embodiment of the present invention, the coefficients of thermal expansion in α₂ (270° C.˜300° C.) zone were remarkably lowered as compared to Samples of Comparative Examples 1 and 2 prepared by using the insulating resin composition which does not include the oligomer of phenyl methane maleimide that is the bismaleimide resin and bis(2,7-bis(2,3-epoxypropoxy))dinaphthalene methane that is the 4-functional naphthalene-based epoxy resin.

In addition, it may be appreciated that in Samples of Examples 1 and 3 prepared by including the oligomer of phenyl methane maleimide that is the bismaleimide resin and bis(2,7-bis(2,3-epoxypropoxy))dinaphthalene methane that is the 4-functional naphthalene-based epoxy resin in the insulating resin composition, the glass transition temperatures were remarkably higher than those of Samples of Comparative Examples 1 and 2.

Samples prepared by Examples 4 and 5 included the inorganic filler in the composition, thereby significantly improving the coefficient of thermal expansion. In addition, a product fabricated by Example 6 is prepreg prepared by impregnating the inorganic fiber or the organic fiber into the varnish containing the resin composition, and a product fabricated by Example 7 is a printed circuit board manufactured by using the prepreg.

As set forth above, the insulating resin composition for the printed circuit board according to the preferred embodiment of the present invention, and the products manufactured by using the same may have the improved coefficient of thermal expansion and glass transition temperature properties.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An insulating resin composition for a printed circuit board comprising:
a liquid crystal oligomer (LCO);
a 4-functional naphthalene-based epoxy resin; and
a bismaleimide resin.

2. The insulating resin composition as set forth in claim 1, wherein the insulating resin composition includes the liquid crystal oligomer (LCO) in an amount of 30 to 55 wt %, the 4-functional naphthalene-based epoxy resin in an amount of 30 to 55 wt %, and the bismaleimide resin in an amount of 10 to 40 wt %.

3. The insulating resin composition as set forth in claim 1, wherein the liquid crystal oligomer is represented by the following Chemical Formula 1: 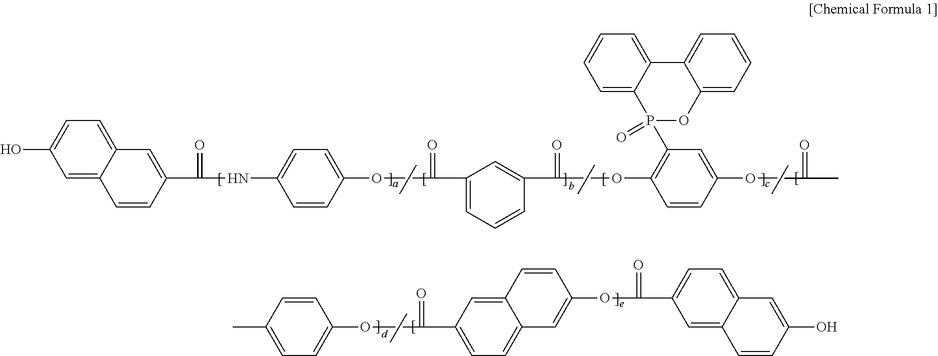
in Chemical Formula 1, a is an integer of 13 to 26, b is an integer of 13 to 26, c is an integer of 9 to 21, d is an integer of 10 to 30, and e is an integer of 10 to 30.

4. The insulating resin composition as set forth in claim 1, wherein the 4-functional naphthalene-based epoxy resin is bis(2,7-bis(2,3-epoxypropoxy))dinaphthalene methane represented by the following Chemical Formula 2:

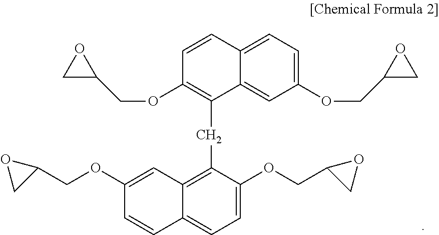 [SMILES: c1cc2ccc(OCC3CO3)c(Cc3c(OCC4CO4)ccc4ccc(OCC5CO5)cc34)c2cc1OCC1CO1]

5. The insulating resin composition as set forth in claim 1, wherein the bismaleimide resin is an oligomer of phenyl methane maleimide represented by the following Chemical Formula 3: 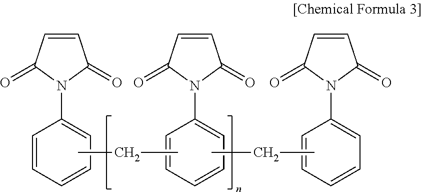
in Chemical Formula 3, n is an integer of 1 or 2.

6. The insulating resin composition as set forth in claim 1, further comprising an inorganic filler, a curing agent, a curing accelerator, and an initiator.

7. The insulating resin composition as set forth in claim 6, wherein the inorganic filler is included in an amount of 100 to 400 parts by weight based on 100 parts by weight of the insulating resin composition, and is at least one selected from silica (SiO₂), alumina (Al₂O₃), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

8. The insulating resin composition as set forth in claim 6, wherein the curing agent is included in an amount of 0.1 to 10 parts by weight based on 100 parts by weight of the insulating resin composition, and is at least one selected from an amine-based curing agent, an acid anhydride-based curing agent, a polyamine curing agent, a polysulfide curing agent, a phenol novolak type curing agent, a bisphenol A type curing agent, and a dicyandiamide curing agent.

9. The insulating resin composition as set forth in claim 6, wherein the curing accelerator is included in an amount of 0.10 to 1 part by weight based on 100 parts by weight of the insulating resin composition, and is at least one selected from a metal-based curing accelerator, an imidazole-based curing accelerator, and an amine-based curing accelerator.

10. The insulating resin composition as set forth in claim 6, wherein the initiator is at least one selected from azobisisobutyronitrile (AIBN), dicumyl peroxide (DCP) and di-tertiarybutyl peroxide (DTBP).

11. A prepreg prepared by impregnating an inorganic fiber or an organic fiber into a varnish containing the insulating resin composition as set forth in claim 1.

12. The prepreg as set forth in claim 11, wherein the inorganic fiber or the organic fiber is at least one selected from a glass fiber, a carbon fiber, a polyparaphenylene benzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber.

13. A printed circuit board manufactured by using the prepreg as set forth in claim 11.
